(19) United States
(12) Patent Application Publication
(10) Pub. No.: US 2026/0190194 A1
(43) Pub. Date: Jul. 2, 2026

(54) CURRENT REGULATOR ARRANGEMENT FOR A LAMP ARRANGEMENT, AND METHOD FOR OPERATING A LAMP ARRANGEMENT

(71) Applicant: TRUMPF Laser SE, Schramberg (DE)

(72) Inventors: Rainer Flaig, Eschbronn (DE); Oliver Krumm, Villingen-Schwenningen (DE); Thomas Kaiser, Oberwolfach (DE); Sven Digeser, Villingendorf (DE); Arno Jakubaschk, Schramberg (DE)

(21) Appl. No.: 19/550,373

(22) Filed: Feb. 26, 2026

Related U.S. Application Data
(63) Continuation of application No. PCT/EP2024/073986, filed on Aug. 28, 2024.

(30) Foreign Application Priority Data
Sep. 1, 2023 (DE) 10 2023 123 595.8

(51) Int. Cl. H05B 45/375; H01S 5/042; H05B 45/325; H05B 45/345; H05B 45/36; H05B 45/385

(52) U.S. Cl. CPC H05B 45/375; H01S 5/0427; H05B 45/325; H05B 45/345; H05B 45/36; H05B 45/385

(57) ABSTRACT

A current regulator arrangement for a laser diode arrangement, including a DC voltage source that provides an upper and a lower voltage level different than ground and at least one current regulator connected to the DC voltage source and having at least one transformer that is connected at the upper and lower voltage level. The current regulator arrangement further includes a current measuring device that senses an output current of the at least one current regulator and is connected to a control device that generates an actuation signal for the at least one transformer.

### CROSS REFERENCE TO RELATED APPLICATIONS

This application is a continuation of International Application No. PCT/EP 2024/073986 (WO 2025/045906A 1 ), filed on Aug. 28, 2024, and claims benefit to German Patent Application No. DE 10 2023 123 595.8, filed on Sep. 1, 2023. The aforementioned applications are hereby incorporated by reference herein.

### FIELD

The invention relates to a current regulator arrangement and to a method for operating a lamp arrangement.

### BACKGROUND

EP 2 667 687 A1 discloses an operating control device for operating a lamp arrangement, which in particular has a series connection of light-emitting diodes. The operating control device has a transformer that is controlled by a switching signal of a control device and provides an output current at its output. Both a lamp arrangement and an output capacitor are connected to this output. A control switch is actuated by the control device via a pulse-width modulated control signal and is located in series with the lamp arrangement. Before the control switch closes, the output capacitor is charged and the output current is increased during a charging period. This means that the current rise phase is carried out before the control switch is closed, so that, even with small pulse widths of the control signal, flickering effects of the lamp arrangement are avoided.

If laser diodes are to be used as light sources, it is necessary that this is done with high dynamics and high efficiency.

### SUMMARY

In an embodiment, the present disclosure provides a current regulator arrangement for a laser diode arrangement, comprising a DC voltage source that provides an upper and a lower voltage level different than ground and at least one current regulator connected to the DC voltage source and having at least one transformer that is connected at the upper and lower voltage level. The current regulator arrangement further comprises a current measuring device that senses an output current of the at least one current regulator and is connected to a control device that generates an actuation signal for the at least one transformer.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an embodiment of a current regulator arrangement; and

FIG. 2 shows an embodiment of a current regulator arrangement.

### DETAILED DESCRIPTION

In an embodiment, the present disclosure provides a control concept for a lamp arrangement, in particular a laser diode arrangement.

The foregoing is achieved according to the present disclosure by a current regulator arrangement for a lamp arrangement, in particular a laser diode arrangement, having a DC voltage source which provides an upper and a lower voltage level different than ground, having at least one current regulator which is connected to the DC voltage source and has at least one transformer which is connected at the upper and lower voltage level, wherein a current measuring device that senses the output current of the current transformer is provided and is connected to a control device which generates an actuation signal for the transformer.

Because two voltage levels are provided, the current regulator does not have to operate the entire voltage range between 0 volts and the upper voltage level. By providing a lower voltage level, a smaller voltage range needs to be covered, thereby increasing efficiency. This results in fewer switching losses in the transformer, allowing it to be operated at a higher frequency and to be dynamically designed, while simultaneously increasing the efficiency of the overall system. The arrangement according to the present disclosure achieves the dynamics of analog drivers, so that these can be omitted. The current regulator arrangement according to the present disclosure also has a particularly good efficiency when the lamp arrangement is operated with a lower power, for example only 50% of the maximum power.

The DC voltage source is preferably configured to generate the two voltage levels from a mains voltage. This can be achieved, for example, by using a flyback transformer or a resonant transformer in combination with a rectifier.

According to the present disclosure, it is particularly provided that the current of the lamp arrangement is adjusted exclusively via the current regulator. In particular, no voltage measurement is necessary. Furthermore, no switch is provided or necessary for turning the lamp arrangement on and off.

The transformer can have at least one switching element that is controlled by the control device. According to the present disclosure, a clocked current regulator concept with high dynamics and high efficiency is therefore provided. By appropriately controlling the switching element as a function of the measured current, a current for the lamp arrangement can be generated in a particularly reliable and dynamic manner. The current regulator arrangement according to the present disclosure operates without measuring a voltage. In particular, no voltage is set, only the current that powers the lamp arrangement.

The lower voltage level can be at least 65%, preferably at least 70%, of the upper voltage level. This allows for a narrow voltage range to be set, which must be covered by the transformer. The lower voltage level can be adjusted, in particular as a function of the lamp arrangement to be operated. The lower voltage level is preferably slightly lower than the threshold voltage required to switch on a laser diode.

Particular advantages arise when the current regulator is arranged in a floating configuration. The current regulator therefore has no connection to ground. This measure allows for improved EMC performance and prevents the controller from being affected by an unwanted ground fault. For example, a ground fault can be detected via an additional voltage measurement and communicated to the user.

A particularly simple embodiment of the transformer results when it is designed as a buck converter. Alternatively, the transformer can be designed as a boost transformer or flyback transformer.

To provide a suitable, low-ripple current, it is advantageous if the current regulator has an inductor. Preferably, the inductor is part of a low-pass filter. According to the present disclosure, it can therefore be provided that a low-pass filter or EMC filter is connected downstream of the transformer.

According to an embodiment of the present disclosure, the current regulator can have a plurality of transformers connected in parallel, which are controlled in a phase-shifted manner. This measure can further increase the dynamics and reduce ripple.

Furthermore, the current regulator arrangement can have a plurality of current regulators connected in parallel, which are controlled in a phase-shifted manner. The current regulator arrangements can control different lamp arrangements, in particular strings of laser diodes. This measure also reduces ripple in a laser arrangement which has a plurality of such strings of laser diodes.

An embodiment of the present disclosure also includes a method for operating a lamp arrangement, in particular a laser diode arrangement, having the following method steps:
providing a first and a second DC voltage level,
sensing the current at the output of a current regulator,
generating an actuation signal to actuate a transformer of the current regulator, which transformer is connected to the first and second voltage levels, as a function of the measured current, in order to generate a predetermined current through the current regulator.

The current for the lamp arrangement is therefore adjusted by current modulation. The current is generated exclusively by a current regulator, without the need for voltage measurement. Because two DC voltage levels are used to which the transformer is connected, only small voltage differences need to be overcome. This can reduce switching losses which can occur at a switching element in the transformer. Furthermore, a high degree of dynamics is made possible.

In particular, the duty cycle of the actuation signal can be adjusted as a function of the measured current. This measure allows the current strength of the output current of the current regulator to be adjusted. In particular, this measure eliminates the need to provide a switch in series with the lamp arrangement to turn it on and off. This significantly reduces the control and circuitry requirements compared to the prior art.

The control signal can preferably be generated with a frequency in the range of 500 kHz to 2 MHz, in particular 1 MHz. Thus, the method can be realized at a very high clock frequency, in particular a significantly higher clock frequency than in the prior art.

To reduce ripple, a plurality of transformers can be actuated with phase-shifted actuation signals. All transformers can be controlled with signals of the same frequency.

Further features and advantages of the present disclosure are evident from the following detailed description of exemplary embodiments, with reference to the figures of the drawings. The features shown are to be understood as not necessarily to scale and are illustrated in such a way that the special features according to the present disclosure can be made distinctly visible. The various features can be realized in each case individually by themselves or as a plurality in any desired combinations in variants of the present disclosure.

The schematic drawing illustrates exemplary embodiments of the present disclosure and are explained in more detail in the description which follows.

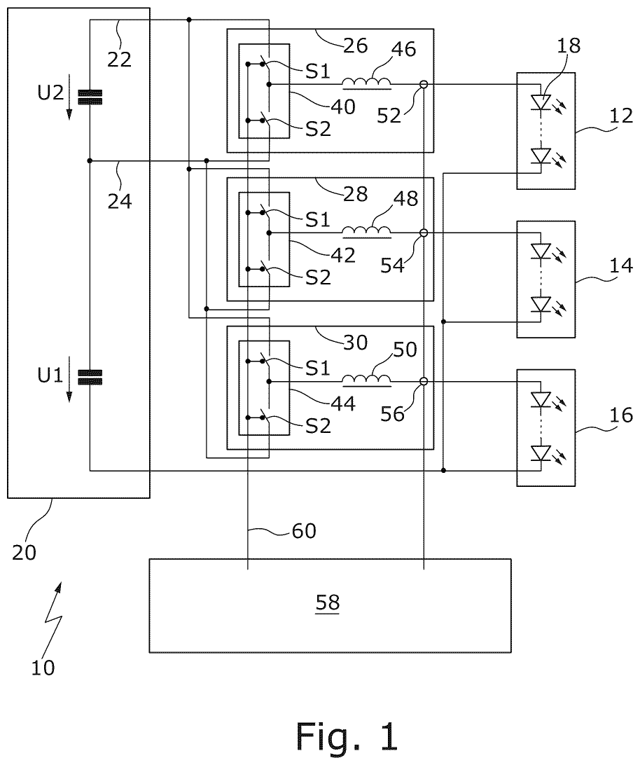

FIG. 1 shows a current regulator arrangement 10 for a lamp arrangement 12, with further lamp arrangements 14, 16 shown in the illustrated exemplary embodiment. In the illustrated exemplary embodiment, the lamp arrangements 12, 14, 16 have series circuits of laser diodes 18. Other configurations of the laser diodes 18 can also be provided.

A DC voltage source 20 provides an upper voltage level 22 and a lower voltage level 24. The lower voltage level 24 is different than ground. In the exemplary embodiment shown in FIG. 1, a plurality of current regulators 26, 28, 30 is provided, which regulators are connected in parallel to the upper and lower voltage levels 22, 24. One of the lamp arrangements 12, 14, 16 is connected to the output of each of the current regulators 26, 28, 30.

Each current regulator 26, 28, 30 has a transformer 40, 42, 44, which in the exemplary embodiment are designed as buck converters. Each transformer 40, 42, 44 has two switching elements S1, S2. An inductor 46, 48, 50 is connected between each of the switching elements S1, S2. The inductors 46, 48, 50 can be part of a low-pass filter. A current measuring device 52, 54, 56 is arranged at the output of the inductors and thus at the output of the current regulators 26, 28, 30. These current measuring devices 52, 54, 56 each sense the current supplied by the current regulators 26, 28, 30 and feed it to a control device 58. Taking into account the measured current, the control device 58 generates an actuation signal 60 of a specified frequency for the transformers 40, 42, 44. The switching elements S1, S2 of the different transformers 40, 42, 44 can be controlled in a phase-shifted manner.

By adjusting the duty cycle of the actuation signal 60, which can have a frequency of 1 MHz, the current generated by the respective current regulator 26, 28, 30 can be adjusted. It is therefore not necessary to provide an additional switch in series with the lamp arrangements 12, 14, 16. Furthermore, it is not necessary to measure a voltage and take it into account when generating the actuation signal. It can also be seen that the current regulators 26, 28, 30 are arranged in a floating configuration. The transformers 40, 42, 44 only need to switch the voltage difference between the upper voltage level 22 and the lower voltage level 24 corresponding to the voltage U2. As a result, the concept according to the present disclosure exhibits high dynamics and high efficiency.

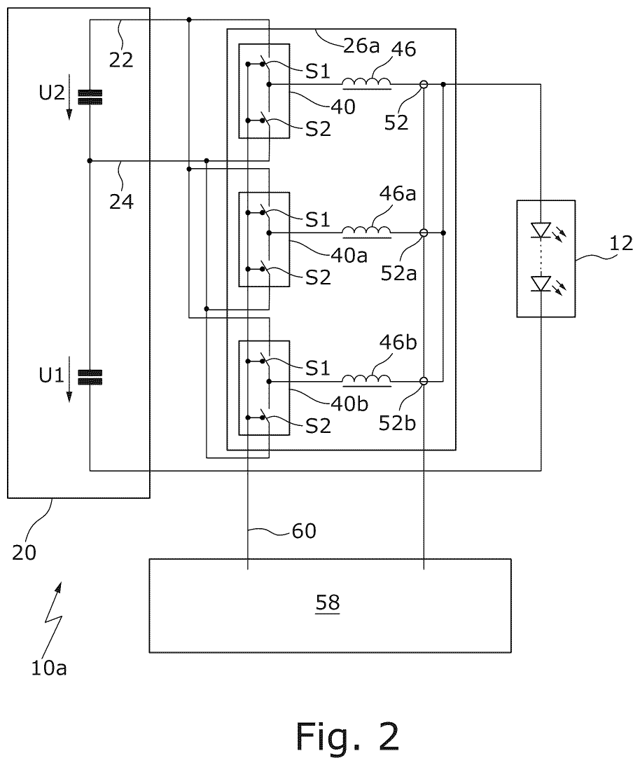

In the embodiment of a current regulator arrangement 10a according to FIG. 2, a DC voltage source 20 is also provided, which provides an upper and lower voltage level 22, 24. In this embodiment, the current regulator 26a assigned to the lamp arrangement 12 has a plurality of transformers 40, 40a, 40b which are connected in parallel to the upper and lower voltage levels 22, 24. Accordingly, inductors 46, 46a, 46b are connected downstream of the transformers 40, 40a, 40b. Current devices 52, 52a, 52b are provided at the output of the inductors 46, 46a, 46b. The current measuring devices 52, 52a, 52b sense the output current at the respective inductors 46, 46a, 46b. In particular, the current measuring devices 52, 52a, 52b, as well as the current measuring devices 52, 54, 56 described in FIG. 1, are arranged between the inductors 46, 48, 50, 46, 46a, 46b and the lamp arrangements 12, 14, 16. The sensed current is taken into account by a control device 58 in order to generate an actuation signal 60 for the transformers 40, 40a, 40b. The switching elements S1, S2 of the respective transformers 40, 40a, 40b are controlled in a phase-shifted manner in order to reduce ripple.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A current regulator arrangement for a laser diode arrangement, comprising:
a DC voltage source that provides an upper and a lower voltage level different than ground;
at least one current regulator connected to the DC voltage source and having at least one transformer that is connected at the upper and lower voltage level; and
a current measuring device that senses an output current of the at least one current regulator and is connected to a control device that generates an actuation signal for the at least one transformer.

2. The current regulator arrangement according to claim 1, wherein the at least one transformer has at least one switching element that is controlled by the control device.

3. The current regulator arrangement according to claim 1, wherein the lower voltage level is at least 65% of the upper voltage level.

4. The current regulator arrangement according to claim 1, wherein the at least one current regulator is arranged in a floating configuration.

5. The current regulator arrangement according to claim 1, wherein the at least one transformer is configured as a buck converter.

6. The current regulator arrangement according to claim 1, wherein the at least one current regulator has an inductor.

7. The current regulator arrangement according to claim 1, wherein the at least one transformer includes a plurality of parallel-connected transformers, and wherein the at least one current regulator has the plurality of parallel-connected transformers, the plurality of parallel-connected transformers being controlled in a phase-shifted manner.

8. The current regulator arrangement according to claim 1, wherein the at least one current regulator includes aa plurality of parallel connected current regulators controlled in a phase-shifted manner.

9. A method for operating a laser diode arrangement, the method comprising:
providing a first and a second DC voltage level;
measuring a current at an output of a current regulator;
generating an actuation signal to actuate a transformer of the current regulator the transformer being connected to the first and second DC voltage levels as a function of the measured current to generate a predetermined current through the current regulator.

10. The method according to claim 9, wherein a duty cycle of the actuation signal is adjusted as a function of the measured current.

11. The method according to claim 9, wherein the actuation signal is generated with a frequency in a range of 500 kHz-2 MHz.

12. The method according to claim 1, wherein the at least one transformer includes a plurality of transformers controlled with phase-shifted actuation signals.

13. The current regulator arrangement according to claim 3, wherein the lower voltage level is at least 70% of the upper voltage level.

14. The current regulator arrangement according to claim 6, wherein the inductor is part of a low pass filter.

15. The method according to claim 11, wherein the actuation signal is generated with a frequency of 1 MHz.
